(19) United States
(12) Patent Application Publication
(10) Pub. No.: US 2013/0252427 A1
(43) Pub. Date: Sep. 26, 2013

(54) METHOD FOR CLEANING TEXTURED SILICON WAFERS

(71) Applicant: Guanghua Song, Fremont, CA (US)

(72) Inventor: Guanghua Song, Fremont, CA (US)

(73) Assignee: SUNPREME, LTD., Sunnyvale, CA (US)

(21) Appl. No.: 13/430,587

(22) Filed: Mar. 26, 2012

(51) Int. Cl. H01L 21/311; B44C 1/22; C23G 1/02; B08B 3/08; C23G 1/14

(52) U.S. Cl. 438/694; 134/25.4; 134/2; 134/3; 216/83; 257/E21.249

(57) ABSTRACT

Substrates for solar cells are prepared by the reverse of the standard RCA clean. The substrates are first cleaned in RCA-2 solution and then in RCA-1 solution. A pyramids rounding step using HF/HNO₃ solution is inserted between the two RCA clean procedures. This solves all the issues relating to surface contaminations and sharp areas. It also avoids the stain layer on the surface to some extent by RCA-1 treatment. A thin layer of amorphous or micro-crystalline intrinsic silicon may be deposited to passivate the surface.

### RELATED APPLICATIONS

The subject Application claims priority benefit to U.S. Provisional Application No. 98/85656, filed on Apr. 14, 2011, the disclosure of which is incorporated herein by reference in its entirety.

### BACKGROUND

1. Field of the Invention

The subject invention relates to low cost silicon, which may be used for fabricating solar photovoltaic cells, light emitting diodes, etc.

2. Related Art

Fabrication of a solar cell involves many of process steps. Substrate surface cleaning is generally performed right after the surface texturing of the Silicon substrate, to remove contaminants left by the texturing process. For solar cell using diffusion junction as emitter, the surface cleaning includes two major steps namely, neutralization and strip of surface oxide. The neutralization is performed using either diluted HCL or H₂SO₄ to remove the remaining alkaline and other metallic particles on the surface. After a rinse by de-ionized water (DI water), the surface oxide is stripped off by diluted hydrofluoric acid (HF) followed by a full DI water rinse. Such a cleaning procedure is sufficient for next fabrication step—i.e., the diffusion process.

For solar cell using heterojunction, the surface has to be extensively treated after texturing process, meaning the above method is insufficient. After surface cleaning, a thin film CVD a-Si deposition is performed, which requires a purely-fresh surface free of any contaminations. So the interface property is the most critical portion for heterojunction.

The widely used cleaning procedure for semiconductor manufacturing is RCA clean. The RCA clean was developed by Radio Corporation of America before 1986. This cleaning procedure includes RCA-1 and RCA-2. RCA-1 involves removal of organic contaminations and RCA-2 involves removal of metallic contaminations. Both RCA-1 and RCA-2 result in a thin silicon oxide formation of about 10 Å on the surface that needs to be stripped off by diluted HF. Generally, RCA-1 (also referred to as SC-1 for Standard Clean), involves processing the wafers in a 1:1:5 solution of NH4OH (ammonium hydroxide)+H2O2 (hydrogen peroxide)+H2O (water) at 75 or 80° C., typically for 10 minutes. This treatment results in the formation of a thin silicon dioxide layer (about 10 Angstrom) on the silicon surface, along with a certain degree of metallic contamination (notably Iron) that should be removed in subsequent steps. This step may be followed by DI rinse and then immersion in 1:50 solution of HF+H2O at 25° C., in order to remove the thin oxide layer and some fraction of ionic contaminants. Next, a second clean, (also called SC-2) is performed with a 1:1:6 solution of HCl+H2O2+H2O at 75 or 80° C. This treatment effectively removes the remaining traces of metallic (ionic) contaminants.

The cleaning procedure for solar cell using diffusion junction is insufficient to remove the surface contaminations. The RCA clean for semiconductor manufacturing is sufficient to remove the surface contaminations. However, another issue prevents this method to be directly applied to solar cell using heterojunction, an interface dominated device structure. This issue is addressed as following.

For alkaline textured Si surface, a pyramidal structure is formed on the surface where it is full of sharp peaks and valleys. The sharp peaks and valleys without any treatment are unable to be efficiently passivated by thin film CVD a-Si in a range from tens of angstroms to about a hundred of angstroms. For a qualified passivation, a conformal growth of thin film CVD a-Si is required for the full surface including the sharp areas—peaks and valleys and flat areas—the facets of formed pyramids and other un-textured portions. This applies to both textured mono-crystalline Si and multi-crystalline Si. Directly depositing thin film CVD a-Si on the RCA cleaned-surface results in a high surface recombination velocity (SRV) and a possible shunting at sharp areas where the a-Si film is much thinner than the flat areas, eventually a low open circuit voltage occurred for the fabricated devices.

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Various embodiments of the subject invention provide methods used to remove the surface contaminations and round the pyramids formed by texturing process, making the surface much more favorable for thin film CVD a-Si deposition. The process flow is specially designed with integration of major process steps including RCA-1, RCA-2 and rounding of the pyramids.

According to embodiments of the invention, the reverse of the standard RCA clean is performed, and a pyramids rounding step using HF/HNO₃ solution is inserted between the two RCA clean procedures. This solves all of the issues relating to surface contaminations and sharp areas. It also avoids the stain layer on the surface to some extent by RCA-1 treatment.

### BRIEF DESCRIPTION OF THE DRAWINGS

Other aspects and features of the invention would be apparent from the detailed description, which is made with reference to the following drawings. It should be appreciated that the detailed description and the drawings provides various non-limiting examples of various embodiments of the invention, which is defined by the appended claims.

The accompanying drawings, which are incorporated in and constitute a part of this specification, exemplify the embodiments of the present invention and, together with the description, serve to explain and illustrate principles of the invention. The drawings are intended to illustrate features of the exemplary embodiments in a diagrammatic manner. The drawings are not intended to depict every feature of actual embodiments nor relative dimensions of the depicted elements, and are not drawn to scale.

FIG. 1 is a flow chart illustrating a process according to an embodiment the invention.

### DETAILED DESCRIPTION

Embodiments of the subject invention provide methods for cleaning substrates used for fabrication of devices such as, e.g., solar cells and light emitting diodes. After surface texturing of Si substrate by, e.g., low concentrated alkaline solution, the surface contains KOH residuals, metallic particles and organic residuals resulting from the surface active agents. After a full rinse of DI water, the substrates are immersed in RCA-2 solution to neutralize KOH residuals, and at the same time to remove the metallic particles on the surface. RCA-2 can be replaced by H₂SO₄/H₂O₂ solution, also known in the art as “Piranha Clean.” Then, the substrates are fully rinsed by DI water and dried by warm air. The next step is using a solution containing hydrofluoric acid (49-50% HF) and nitric acid (69-70% HNO₃) at a concentration about 1:25 to round the pyramids. This step performs the etching of Si at an etching speed of a few hundreds of angstroms per second, producing a fresh Si surface. The etching speed at sharp areas is slightly different, causing a rounding effect. It also burns out the organic residuals attached to the surface. Afterwards, the substrates are quickly transferred to DI water rinsing tank for a thorough rinse followed by a diluted HF (2%) and hydrochloric acid-HCL (2%) immersion to strip off the surface oxide and metallic particles. Failure to improperly perform this step may result in a stubborn yellowish stain layer on the surface, resulting from an unsuccessful removal of by-products from the reaction between Si and HF/HNO₃. The substrates then are rinsed by DI water followed by RCA-1 clean to again remove the organic residuals, and at the same time to etch off a very little amount of Si. RCA-1 also helps to remove the possibly formed stain layer from the surface. After the RCA-1 clean, the substrates are rinsed by DI water followed by diluted HF (2%) and HCL (2%) to strip off the surface oxide and remove the metallic particles. The substrates are finally rinsed by DI water and dried by hot nitrogen gas, leaving a fresh hydrophobic surface for thin film CVD a-Si passivation. The complete process flow is listed as following.

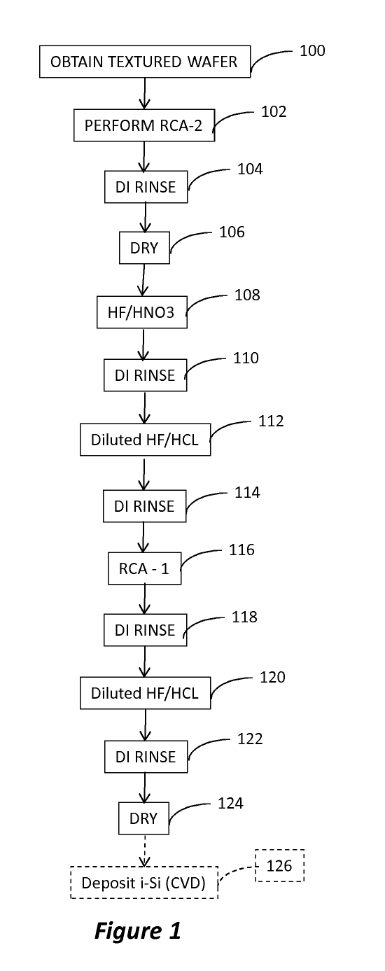

FIG. 1 is a flowchart illustrating a process according to an embodiment of the invention. In FIG. 1, the process starts in step 100 by obtaining textured silicon substrates. The texture can be obtained any using standard procedures known in the art, e.g., using wet or dry etch. In step 102 an RCA-2 process is performed on the substrates, using a mixture of HCL:H2O2:H2O at ratio of 1:1:6, at temperature: 70-80 C, for about 10 minutes. The wafers are then rinsed in DI water for 2 minutes (step 104) and then dry in warm air, at temperature of about 60-80 C (step 106). The wafers are then immersed in a HF/HNO3 solution, at ratio of about 1:20-30, for about 30-120 seconds (step 108). At step 110 the wafers are rinsed in DI water for about 2.5 minutes. At step 112 the wafers are immersed in diluted HF/HCL of about 2% HF+2% HCL, for about 2 minutes. The wafers are then rinsed in DI water for about 2 minutes. Then, at step 116 an RCA-1 clean is performed, using a mixture of NH4OH:H2O2:H2O=1:1:5, Temperature: 70-80 C, Time: 10 minutes. The wafers are then rinsed in DI water for about 2 minutes. At step 120 the wafers are immersed in diluted HF/HCL immersion, mixed 2% HF+2% HCL, for about 2 minutes, and then at step 122 are rinsed in DI water for about 2 minutes. The wafers are then dried in hot N2 for about 10-15 minutes.

According to one specific embodiment, once the wafers are dry, they are transferred to a deposition system, such as a chemical vapor deposition (CVD) or Plasma Enhanced chemical vapor deposition (PECVD) and a thin layer of intrinsic amorphous or micro-crystalline silicon (i-Si) is deposited on the texturized surface. This step passivates the surface of the wafers. The i-Si layer can be, e.g., 50-200 micron thick. This passivation step also increases the minority carriers lifetime in the wafers, since combination sites on the surface are eliminated by the i-Si layer.

It should be understood that processes and techniques described herein are not inherently related to any particular apparatus and may be implemented by any suitable combination of components. Further, various types of general purpose devices may be used in accordance with the teachings described herein. It may also prove advantageous to construct specialized apparatus to perform the method steps described herein. The present invention has been described in relation to particular examples, which are intended in all respects to be illustrative rather than restrictive. Those skilled in the art will appreciate that many different combinations of hardware, software, and firmware will be suitable for practicing the present invention.

The present invention has been described in relation to particular examples, which are intended in all respects to be illustrative rather than restrictive. Those skilled in the art will appreciate that many different combinations of hardware, software, and firmware will be suitable for practicing the present invention. Moreover, other implementations of the invention will be apparent to those skilled in the art from consideration of the specification and practice of the invention disclosed herein. It is intended that the specification and examples be considered as exemplary only, with a true scope and spirit of the invention being indicated by the following claims.

1. A method for preparing substrates, comprising performing the steps in the following order:
obtaining textured wafers having sharp pyramids surface;
performing RCA-2 cleaning on the wafer;
performing a smoothing etch on the wafer;
performing RCA-1 cleaning on the wafer.

2. The method of claim 1, wherein performing smoothing etch comprises immersing the wafer in a HF/HNO3 solution.

3. The method of claim 2, further comprising immersing the wafer in diluted HF solution prior to the RCA-1 cleaning and immersing the wafer in diluted HF solution after the RCA-1 cleaning.

4. The method of claim 3, further performing DI wafer rinse after each immersion in diluted HF solution.

5. The method of claim 4, further comprising drying the wafer in hot N2 atmosphere.

6. The method of claim 1 wherein performing a smoothing etch comprises immersing the wafer in HF/HNO3 solution at ratio of about 1:20-30, for about 30-120 seconds.

7. The method of claim 1, further comprising a step of depositing a thin layer of intrinsic amorphous or micro-crystalline silicon on the texturized surface at the end of processing the wafers.

8. A method for preparing substrates, comprising performing the steps in the following order:
obtaining textured silicon wafers having texturized surface;
immersing the wafers in a chemical solution to thereby remove the metallic particles present on the texturized surface and to neutralize any KOH residuals present on the texturized surface;
smoothing sharp edges on the texturized surface of the wafers;
immersing the wafers in a chemical solution to thereby remove the organic residuals; and,
rinsing and drying the wafers.

9. The method of claim 8, wherein the step of immersing the wafers in a chemical solution to thereby remove the metallic particles comprises immersing the wafers in RCA-2 solution.

10. The method of claim 8, wherein the step of immersing the wafers in a chemical solution to thereby remove the metallic particles comprises immersing the wafers in H₂SO₄/H₂O₂ solution.

11. The method of claim 8, wherein the step of immersing the wafers in a chemical solution to thereby remove the organic residuals comprises immersing the wafers in an RCA-1 solution.

12. The method of claim 8, wherein the step of smoothing sharp edges on the texturized surface of the wafers comprises immersing the wafers in a solution of hydrofluoric acid and nitric acid.

13. The method of claim 8, further comprising a step of depositing a thin layer of intrinsic amorphous or micro-crystalline silicon on the texturized surface after the step of rinsing and drying the wafers.

14. The method of claim 8, further comprising the steps of rinsing the wafers in DI water following each step of claim 8.

15. The method of claim 8, wherein:
the step of immersing the wafers in a chemical solution to thereby remove the metallic particles comprises immersing the wafers in HCL:H2O2:H2O at ratio of 1:1:6, at temperature of 70-80 C;
the step of smoothing sharp edges on the texturized surface comprises immersing the wafers in diluted HF/HCL solution; and,
the step of immersing the wafers in a chemical solution to thereby remove the organic residuals comprises immersing the wafers in a xsolution of NH4OH:H2O2:H2O at ratio of 1:1:5, at temperature of 70-80 C.

16. The method of claim 8, wherein the step of obtaining textured silicon wafers having texturized surface comprises obtaining silicon wafers and immersing the wafer in an alkaline solution to texturize the surface of the wafers.
